(19) United States
(12) Patent Application Publication
(10) Pub. No.: US 2025/0336709 A1
(43) Pub. Date: Oct. 30, 2025

(54) CONVEYANCE ARM AND SUBSTRATE CONVEYANCE DEVICE

(71) Applicant: TOKYO ELECTRON LIMITED, Tokyo (JP)

(72) Inventors: Keisuke KONDOH, Yamanashi (JP); Tomonori IWASAKI, Yamanashi (JP)

(21) Appl. No.: 18/727,854

(22) PCT Filed: Jan. 5, 2023
(86) PCT No.: PCT/JP2023/000082

§ 371 Date: Jan. 13, 2025

(30) Foreign Application Priority Data
Jan. 12, 2022 (JP) 2022-003019
Oct. 27, 2022 (JP) 2022-172728

(51) Int. Cl. H01L 21/683; B25J 15/06; H01L 21/67; H01L 21/677

(52) U.S. Cl. CPC H01L 21/6838; B25J 15/0616; H01L 21/67242; H01L 21/67742; H01L 21/67748

(57) ABSTRACT

This conveyance arm conveys a substrate by means of vacuum suction under atmospheric pressure, and includes a pick that holds the substrate, and a plurality of holding pads provided on the surface of the pick, wherein the holding pads each have a base part provided on the front surface of the pick and having a vacuum-suctioning through-hole formed therein, and an annular part provided annularly on the surface of the base part and contacting the rear surface of the substrate, and a protrusion is formed on a portion of the annular part in a direction intersecting an annular direction of the annular part. A substrate conveyance device for conveying a substrate under atmospheric pressure includes said conveyance arm.

### TECHNICAL FIELD

The present disclosure relates to a transfer arm and a substrate transfer device.

### BACKGROUND

Patent Document 1 discloses a substrate transfer device that transfers a substrate by vacuum suction/attraction. The substrate transfer device includes a flange portion, a plurality of pads for holding a substrate, and a hand for detachably fixing the plurality of pads. The flange portion is formed in a circular shape.

### PRIOR ART DOCUMENTS

### Patent Documents

Patent Document 1: Japanese Laid-open Patent Publication No. 2015-103696

### SUMMARY

### Problems to Be Resolved by the Invention

The technique of the present disclosure improves detachability of a substrate from a transfer arm for vacuum-suctioning and transferring a substrate in an atmospheric environment.

### Means for Solving the Problems

One aspect of the present disclosure relates to a transfer arm for vacuum suctioning and transferring a substrate under an atmospheric atmosphere. The transfer arm comprises; a pick configured to hold a substrate; and a plurality of holding pads disposed on a surface of the pick, wherein each of the holding pads includes: a base part disposed on a surface of the pick and having a through-hole for vacuum suction; and an annular part disposed in an annular shape on the surface of the base part and configured to be in contact with a backside of the substrate, wherein a part of the annular part has a projecting portion formed in a direction intersecting with an annular direction of the annular part.

### Effect of the Invention

In accordance with the present disclosure, it is possible to improve detachability of a substrate from a transfer arm for vacuum suctioning and transferring a substrate in an atmospheric environment.

### BRIEF DESCRIPTION OF THE DRAWINGS

FIG. 1 is a plan view schematically showing a configuration of a wafer processing apparatus according to the present embodiment.

FIG. 2 is a perspective view schematically showing a configuration of a transfer arm.

FIG. 3 is a perspective view schematically showing a configuration of a holding pad.

FIG. 4 is a perspective view schematically showing the configuration of the holding pad.

FIG. 5 is a perspective view schematically showing the configuration of the holding pad and a base.

FIG. 6 is a perspective view schematically showing the configuration of the holding pad.

FIG. 7 is an explanatory diagram showing arrangement of holding pads on a pick.

FIG. 8A is a plan view schematically showing the configuration of the holding pad.

FIG. 8B is a plan view schematically showing the configuration of the holding pad.

FIG. 8C is a plan view schematically showing the configuration of the holding pad.

FIG. 8D is a plan view schematically showing the configuration of the holding pad.

FIG. 8E is a plan view schematically showing the configuration of a holding pad.

FIG. 8F is a plan view schematically showing the configuration of the holding pad.

FIG. 8G is a plan view schematically showing the configuration of the holding pad.

FIG. 8H is a plan view schematically showing the configuration of the holding pad.

FIG. 8I is a plan view schematically showing the configuration of the holding pad.

FIG. 9 is a perspective view schematically showing the configuration of the holding pad.

FIG. 10 is a perspective view schematically showing the configuration of the holding pad.

FIG. 11 is a perspective view schematically showing the configuration of the holding pad.

FIG. 12A is a plan view schematically showing the configuration of the holding pad.

FIG. 12B is a plan view schematically showing the configuration of the holding pad.

FIG. 12C is a plan view schematically showing the configuration of the holding pad.

FIG. 12D is a plan view schematically showing the configuration of the holding pad.

FIG. 12E is a plan view schematically showing the configuration of the holding pad.

FIG. 12F is a plan view schematically showing the configuration of the holding pad.

FIG. 12G is a plan view schematically showing the configuration of the holding pad.

FIG. 12H is a plan view schematically showing the configuration of the holding pad.

FIG. 12I is a plan view schematically showing the configuration of the holding pad.

FIG. 13 is an explanatory diagram showing an internal configuration of a wafer transfer device.

FIG. 14 is a perspective view schematically showing a configuration of a conventional holding pad.

### DETAILED DESCRIPTION

In a manufacturing process of semiconductor devices, wafer processing such as etching is performed on a semiconductor wafer (substrate; hereinafter, referred to as “wafer”) in a vacuum atmosphere, for example. The wafer processing is performed using a wafer processing apparatus including a plurality of processing modules.

For example, the wafer processing apparatus has a configuration in which a depressurization part under a vacuum atmosphere (under a depressurized atmosphere) and a normal pressure part under an atmospheric atmosphere (under a normal pressure atmosphere) are integrally connected via a load-lock module.

The depressurization part includes a common transfer module, and a plurality of processing modules connected around the transfer module. The wafer is transferred from the transfer module under a vacuum atmosphere to the processing module, and desired processing is performed in the processing module under a vacuum atmosphere.

The normal pressure part includes a load port on which a front opening unified pod (FOUP) capable of storing a plurality of wafers is placed, and a loader module having a wafer transfer device. When the loader module is under an atmospheric atmosphere, the wafer is transferred between the FOUP and the load-lock module.

The load-lock module is configured such that the inner atmosphere thereof can be switched between a vacuum atmosphere and an atmospheric atmosphere, and transfers a wafer between the depressurized part and the normal pressure part.

In the loader module, the wafer transfer device for transferring a wafer in an atmospheric environment vacuum suctions and transfers a wafer using a plurality of pads disposed at a hand (transfer arm), as disclosed in Patent Document 1, for example. Further, when the wafer is transferred from the wafer transfer device to another module, the vacuum suction from the plurality of pads is stopped to detach the wafer.

However, in some cases, it is difficult to detach the wafer from the pads even if the vacuum suction from the pads is stopped. This is due to the adhesiveness of the wafer, for example. However, a conventional pad is not designed to handle a case where it is difficult to detach a wafer. When it is difficult to detach the wafer from the pads, the wafer may jump out of the transfer arm during the transfer of the wafer, or the wafer may remain on the transfer arm without being transferred. Therefore, a conventional wafer transfer device needs to be improved.

The technique of the present disclosure improves detachability of a substrate in a transfer arm that vacuum suctions and transfers a substrate in an atmospheric environment. Hereinafter, a wafer processing apparatus including a wafer transfer device as a substrate transfer device according to the present embodiment will be described with reference to the accompanying drawings. Further, like reference numerals will be used for like parts having substantially the same functions and configurations throughout this specification and the drawings, and redundant description thereof will be omitted.

### Wafer Processing Apparatus

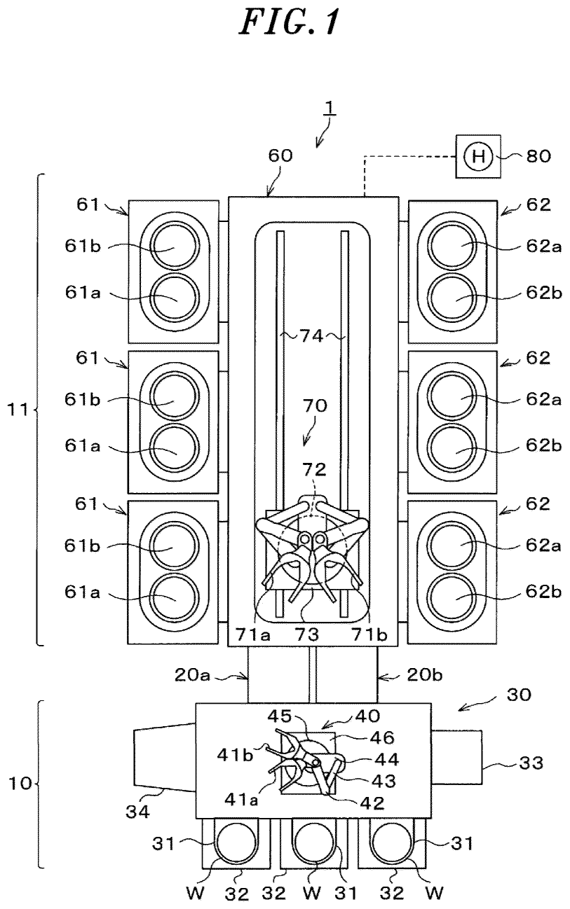

First, a wafer processing apparatus according to the present embodiment will be described. FIG. 1 is a plan view schematically showing a configuration of a wafer processing apparatus 1. In the present embodiment, a case where the wafer processing apparatus 1 includes various processing modules for performing COR processing, PHT processing, and CST processing on a wafer W as a substrate will be described. Further, the configurations of various processing modules of the wafer processing apparatus 1 of the present disclosure are not limited thereto, and may be arbitrarily selected.

As shown in FIG. 1, the wafer processing apparatus 1 has a structure in which a normal pressure part 10 and a depressurized part 11 are integrally connected via load-lock modules 20a and 20b.

The load-lock module 20a temporarily holds the wafer W transferred from a loader module 30 (to be described later) of the normal pressure part 10 in order to transfer it to a transfer module 60 (to be described later) of the depressurization part 11. The load-lock module 20a has a plurality of (e.g., two) stockers (not shown), and thus holds two wafers W at the same time.

The load-lock module 20a is connected to the loader module 30 and the transfer module 60 via gates (not shown) provided with gate valves (not shown). The gate valves ensure airtightness between the load-lock module 20a, the loader module 30, and the transfer module 60 and communication therebetween.

The load-lock module 20a is connected to an air supply part (not shown) for supplying a gas and an exhaust part (not shown) for discharging a gas. The inner atmosphere thereof can be switched between an atmospheric atmosphere (normal pressure atmosphere) and a vacuum atmosphere (depressurized atmosphere) by the air supply part and the exhaust part. In other words, the load-lock module 20a is configured to appropriately transfer the wafer W between the normal pressure part 10 having an atmospheric atmosphere and the depressurized part 11 having a vacuum atmosphere.

The load-lock module 20b temporarily holds the wafer W transferred from the transfer module 60 in order to transfer it to the loader module 30. The load-lock module 20b has the same configuration as that of the load-lock module 20a. in other words, the load-lock module 20b has a gate valve (not shown), a gate (not shown), an air supply part (not shown), and an exhaust part (not shown).

Further, the number and arrangement of the load-lock modules 20a and 20b are not limited to those of the present embodiment, and can be set arbitrarily.

The normal pressure part 10 includes the loader module 30 having a wafer transfer device 40 (to be described later), a load port 32 in which a FOUP 31 capable of storing a plurality of wafers W is placed, a CST module 33 for cooling the wafer W, and an aligner module 34 for adjusting a horizontal orientation of the wafer W.

The loader module 30 includes a rectangular housing, and the housing is maintained at an atmospheric atmosphere. A plurality of, for example, three, load ports 32 are arranged on one side constituting the long side of the housing of the loader module 30. The load-lock modules 20a and 20b are arranged on the other long side of the housing of the loader module 30. The CST module 33 is disposed on one side constituting the short side of the housing of the loader module 30. The aligner module 34 is disposed on the other short side of the housing of the loader module 30.

Further, the number and arrangement of the load port 32, the CST module 33, and the aligner module 34 are not limited to those of the present embodiment, and can be set arbitrarily. Further, types of modules provided in the normal pressure part 10 are not limited to those of the present embodiment, and can be arbitrarily selected.

The FOUP 31 accommodates a plurality of (e.g., 25) wafers W per lot. Further, the FOUP 31 placed in the load port 32 is filled with, e.g., air or nitrogen gas, and is sealed.

The wafer transfer device 40 as a substrate transfer device for transferring the wafer W is disposed in the loader module 30. The wafer transfer device 40 is an articulated robot. The wafer transfer device 40 has transfer arms 41a and 41b for holding and moving the wafer W, three arms 42 to 44, a rotatable table 45 for rotatably supporting the transfer arms 41a and 41b, and a rotatable base 46 on which the rotatable table 45 is placed. The three arms 42 to 44 are connected by joints (not shown), and the arms 42 to 44 are rotatable about base ends thereof by the joints. The transfer arms 41a and 41b are attached to the tip end of the first arm 42, and the base end of the first arm 42 is disposed at the tip end of the second arm 43. The transfer arms 41a and 41b are rotatable by a rotatable part (not shown) disposed at the first arm 42. The base end of the second arm 43 is disposed at the tip end of the third arm 44. The base end of the third arm 44 is disposed at the rotatable table 45. The arms 42 to 44 and the rotatable table 45 have a hollow inner/internal structure. The insides of the arms 42 to 44 and the rotatable table 45 are maintained at an atmospheric atmosphere. Further, the wafer transfer device 40 configured as described above is movable in a longitudinal direction in the housing of the loader module 30.

The depressurization part 11 includes the transfer module 60 for transferring two wafers W at the same time, a COR module 61 for performing COR processing on the wafer W, and a PHT module 62 for performing PHT processing on the wafer W. The transfer module 60, the COR module 61, and the PHT module 62 are maintained in a vacuum atmosphere. Further, a plurality of (e.g., three) COR modules 61 and a plurality of (e.g., three) PHT modules 62 are provided for each transfer module 60, for example.

The transfer module 60 includes a rectangular housing, and is connected to the load-lock modules 20a and 20b via gate valves (not shown) as described above. The transfer module 60 transfers the wafer W loaded into the load-lock module 20a sequentially to one COR module 61 and one PHT module 62 so that the wafer W can be subjected to the COR processing and the PHT processing, and then unloads/discharges the wafer W to the normal pressure part 10 via the load-lock module 20b.

The COR module 61 has therein two stages 61a and 61b on which two wafers W that are horizontally aligned are placed. The COR module 61 performs the COR processing on the two wafers W at the same time in a state where the wafers W are aligned on the stages 61a and 61b. Further, the COR module 61 is connected to an air supply part (not shown) for supplying a processing gas or a purge gas, and an exhaust part (not shown) for discharging a gas.

The PHT module 62 has therein two stages 62a and 62b on which two wafers W that are horizontally aligned are placed. The PHT module 62 performs the PHT processing on the two wafers W at the same time in a state where the wafers W are aligned on the stages 62a and 62b. Further, the PHT module 62 is connected to an air supply part (not shown) for supplying a gas and an exhaust part (not shown) for discharging a gas.

Further, the COR module 61 and the PHT module 62 are connected to the transfer module 60 via gates (not shown) provided with gate valves (not shown). The gate valves ensure airtightness between the transfer module 60, the COR module 61, and the PHT module 62 and communication therebetween.

Further, the number, arrangement, and types of processing modules provided in the transfer module 60 are not limited to those of the present embodiment, and can be set arbitrarily.

A wafer transfer device 70 for transferring the wafer W is disposed in the transfer module 60. The wafer transfer device 70 includes transfer arms 71a and 71b for holding and moving two wafers W, a rotatable table 72 for rotatably supporting the transfer arms 71a and 71b, and a rotatable base 73 on which the rotatable table 72 is placed. Further, a guide rail 74 extending in the longitudinal direction of the transfer module 60 is disposed in the transfer module 60. The rotatable base 73 is disposed on the guide rail 74, and the wafer transfer device 70 is movable along the guide rail 74.

The wafer processing apparatus 1 described above includes a controller 80. The controller 80 is, e.g., a computer including a CPU, a memory, or the like, and has a program storage part (not shown). The program storage part stores a program for controlling processing of the wafer W in the wafer processing apparatus 1. Further, the program may be stored in a computer-readable storage medium H, and may be installed in the controller 80 from the storage medium H. Further, the storage medium H may be temporary or non-transitory.

In the wafer processing apparatus 1 configured as described above, first, the wafer W is transferred from the FOUP 31 to the aligner module 34 by the wafer transfer device 40 under an atmospheric atmosphere, and the horizontal orientation thereof is adjusted. Next, the wafer W is transferred to the load-lock module 20a by the wafer transfer device 40.

Next, the wafer W is transferred to the COR module 61 by the wafer transfer device 70 under a vacuum atmosphere, and subjected to the COR processing. Next, the wafer W is transferred to the PHT module 62 by the wafer transfer device 70, and subjected to the PHT processing. Next, the wafer W is transferred to the load-lock module 20b by the wafer transfer device 70.

Next, the wafer W is transferred to the CST module 33 by the wafer transfer device 40 under an atmospheric atmosphere, and subjected to the CST processing. Next, the wafer W is transferred to the FOUP 31 by the wafer transfer device 40. In this manner, a series of wafer processing in the wafer processing apparatus 1 is completed.

### Transfer Arm

Next, the transfer arms 41a and 41b of the wafer transfer device 40 will be described. The transfer arms 41a and 41b have the same configuration, and will be collectively referred to as “transfer arm 41” below. The transfer arm 41 vacuum suctions and transfers the wafer W.

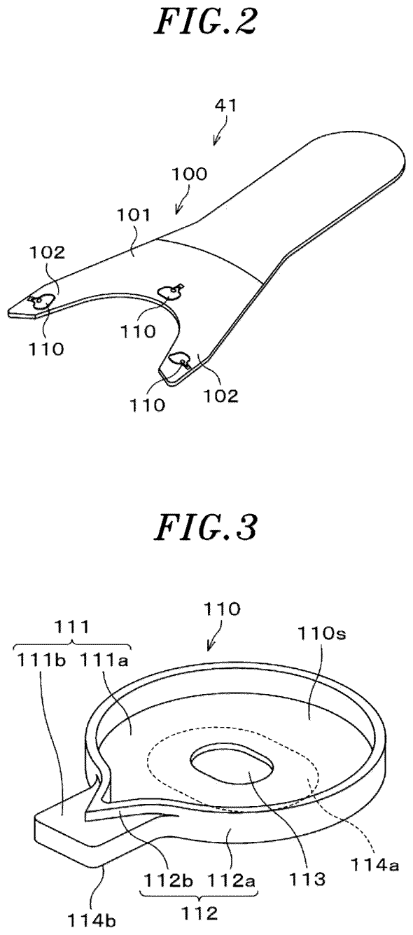

As shown in FIG. 2, the transfer arm 41 has a pick 100 for holding the wafer W, and a plurality of (e.g., three) holding pads 110 disposed on the surface of the pick 100. The pick 100 has a fork shape that branches from a base end 101 into two tip ends 102 and 102. The three holding pads 110 are disposed on the surfaces of the base end 101 and the tip ends 102 and 102, respectively.

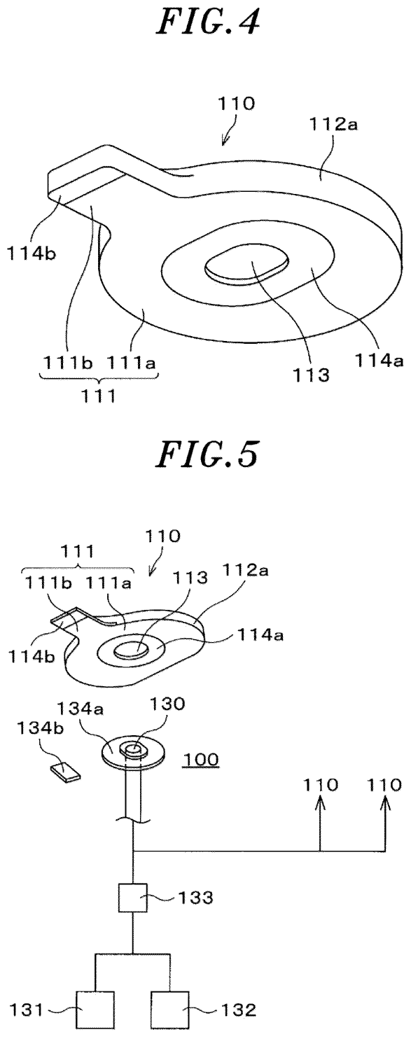

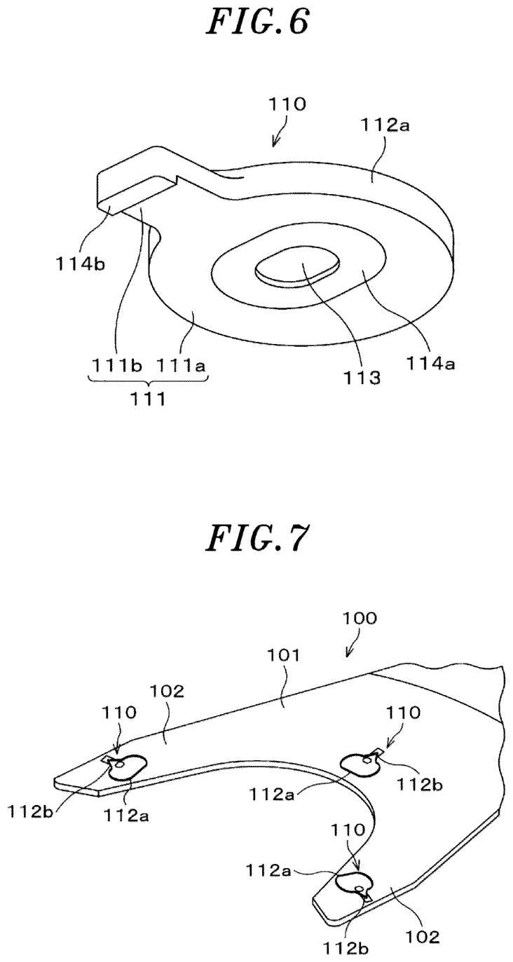

As shown in FIGS. 3 and 4, the holding pad 110 has a base part 111 disposed on the bottom surface and an annular part 112 disposed on the surface of the base part 111. The base part 111 and the annular part 112 are integrally molded.

The annular part 112 has a circular ring-shaped portion 112a and a projecting portion 112b. The circular ring-shaped portion 112a and the projecting portion 112b are integrally molded. The circular ring-shaped portion 112a has a perfect circular annular shape in plan view, for example. The projecting portion 112b projects outward from the circular ring-shaped portion 112a in a direction intersecting the annular direction of the circular ring-shaped portion 112a in plan view, for example. The vertex (top) of the projecting portion 112b is bent at an acute angle.

The base part 111 has an inner base portion 111a and an outer base portion 111b. The inner base portion 111a and the outer base portion 111b are integrally molded. The inner base portion 111a is disposed at the inner side of the annular part 112 along the circular ring-shaped portion 112a and the projecting portion 112b. The outer base portion 111b projects outward from the projecting portion 112b.

A through-hole 113 for vacuum suction is formed in the inner base portion 111a. The through-hole 113 is connected to a gas channel 130 (to be described later), and communicates with an air supply part 131 (to be described later) for supplying a gas into the holding pad 110 and a suction part 132 (to be described later) for suctioning a gas from the holding pad 110.

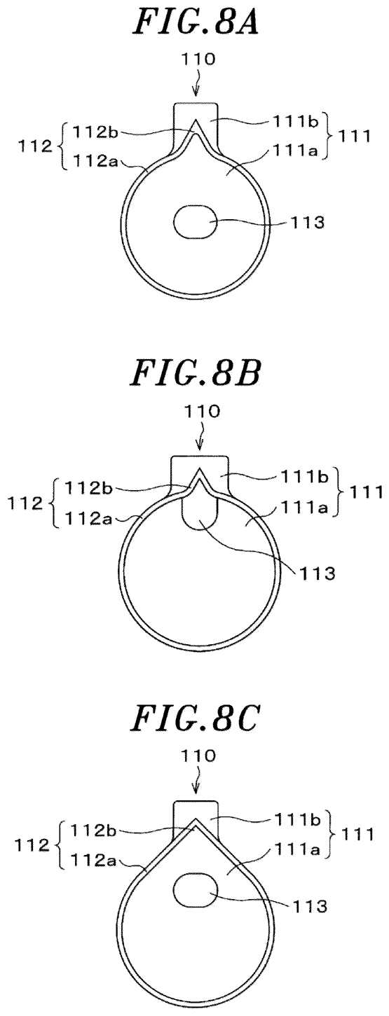

As shown in FIG. 5, the holding pad 110 is fixed to the pick 100 via an adhesive. The gas channel 130 is disposed at the pick 100 to correspond to the through-hole 113. The gas channel 130 extends from the through-hole 113 and penetrates through the three arms 42 to 44. The gas channel 130 communicates with the air supply part 131 for supplying gas into the holding pad 110 and the suction part 132 for suctioning a gas from the holding pad 110. Further, the gas channel 130 is provided with a valve 133 for switching gas supply from the air supply part 131 and gas suction (vacuum adsorption) from the suction part 132. A solenoid valve is used as the valve 133, for example. Further, the air supply part 131, the suction part 132, and the valve 133 are provided in common for the three holding pads 110.

An adhesive surface 134a is formed around the gas channel 130 on the surface of the pick 100. Further, the back surface of the inner base portion 111a constitutes an adhesive surface 114a corresponding to the adhesive surface 134a around the through-hole 113. In other words, the adhesive area (the adhesive surface 114a) on the back surface of the inner base portion 111a is determined by the shape of the adhesive surface 134a. The adhesive surface 114a and the adhesive surface 134a are arranged to face each other, and are adhesively fixed without a gap. By fixing the periphery of the through-hole 113 and the periphery of the gas channel 130 with the adhesive surface 114a and the adhesive surface 134a, gas leakage can be suppressed.

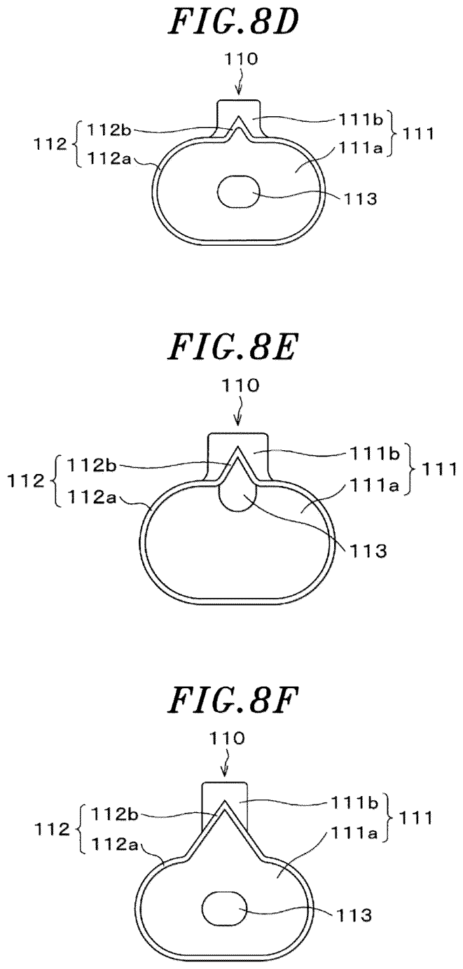

An adhesive surface 114b is formed on the back surface of the outer base portion 111b to correspond to the projecting portion 112b, and an adhesive surface 134b is formed on the surface of the pick 100 to correspond to the projecting portion 112b. The adhesive surface 114b and the adhesive surface 134b are arranged to face each other and adhesively fixed. Due to the adhesive fixing, the rigidity of the projecting portion 112b can be increased. Although the back surface of the outer base portion 111b and the adhesive surface 114b constitute the same surface in the present embodiment, the adhesive surface 114b may project from the back surface of the outer base portion 111b, as shown in FIG. 6, for example.

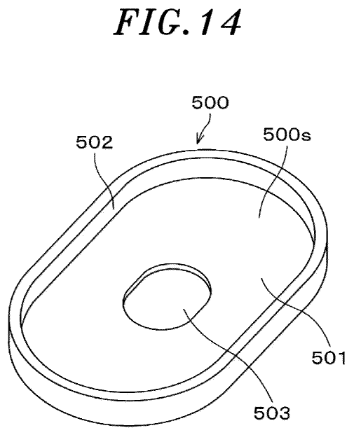

The effects of the holding pad 110 configured as described above will be described in comparison with a conventional holding pad. As shown in FIG. 14, a conventional holding pad 500 has a base portion 501 disposed on the bottom surface, and an annular portion 502 disposed in an annular shape on the surface of the base portion 501. The annular portion 502 has an elliptical shape in plan view. A through-hole 503 for vacuum suction is formed in the base portion 501.

In the case of holding the wafer W with the holding pad 500, a suction space 500s formed by the backside of the wafer W, the base portion 501, and the annular portion 502 is vacuum suctioned in a state where the annular portion 502 is in contact with the backside of the wafer W. On the other hand, in the case of detaching the wafer W from the holding pad 500, the vacuum suction from the suction space 500s is stopped, and a gas is supplied to the suction space 500s, and then the wafer W is lifted (moved) to be delivered to a destination.

However, in some cases, it is difficult to detach the wafer from the holding pad 500 even if the vacuum suction of the suction space 500s is stopped. In other words, the wafer W having adhesiveness is adhered to the annular portion 502, which makes it difficult to detach the wafer W from the holding pad 500.

On the other hand, the holding pad 110 of the present embodiment has the projecting portion 112b as a detachment starting point.

In the case of holding the wafer W by the holding pad 110, a suction space 110s formed between the backside of the wafer W and the inner side of the holding pad 110 is vacuum suctioned by the suction part 132 in a state where the annular part 112 is in contact with the backside of the wafer W.

On the other hand, in the case of detaching the wafer W from the holding pad 110, the vacuum suction from the suction space 110s is stopped, and a gas is supplied from the air supply part 131 to the suction space 110s. Next, when the wafer W is lifted (moved) to be delivered, stress is concentrated on the projecting portion 112b, and the projecting portion 112b becomes the detachment starting point (or removal/breakout point). In this regard, the conventional holding pad 500 does not have a singular point such as the projecting portion 112b, so that stress is not concentrated anywhere on the annular portion 502. Then, the detachment propagates sequentially from the projecting portion 112b toward the circular ring-shaped portion 112a, and the wafer W is detached. Therefore, in accordance with the holding pad 110 of the present embodiment, the detachability of the wafer W can be improved. Further, the outer base portion 111b corresponding to the projecting portion 112b is fixed to the pick 100 via the adhesive surfaces 114b and 134b, and has high rigidity. Hence, stress can be further concentrated on the projecting portion 112b, and the projecting portion 112b can appropriately function as the detachment starting point. Accordingly, the detachability of the wafer W can be further improved.

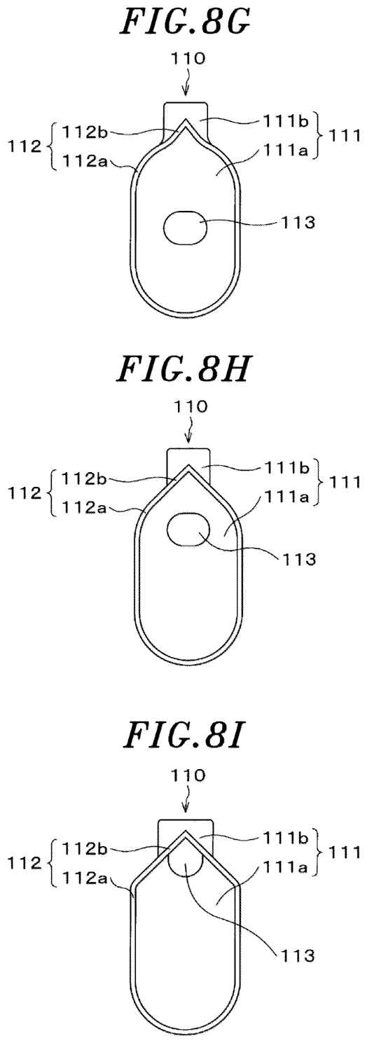

Further, the orientation of the three holding pads 110 on the transfer arm 41, that is, the orientation of the projecting portion 112b with respect to the circular ring-shaped portion 112a, is arbitrary. For example, as shown in FIG. 7, each of the three holding pads 110 may be disposed such that the projecting portion 112b is oriented radially outward from the center of the pick 100 with respect to the circular ring-shaped portion 112a. Due to the characteristics of the holding pad 110, the wafer W may be displaced when it is detached. However, if the projecting portions 112b are arranged radially, the characteristics of the single holding pad 110 may be offset.

Further, in the holding pad 110, the planar shape of the circular ring-shaped portion 112a, the planar shape of the projecting portion 112b, and the arrangement of the through-hole 113 are arbitrary.

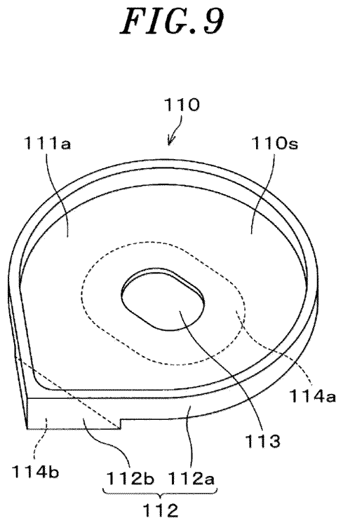

For example, as shown in FIGS. 8A to 8C, the circular ring-shaped portion 112a may have a perfect circular shape in plan view. In FIG. 8A, the through-hole 113 is formed substantially at the center of the circular ring-shaped portion 112a. In FIG. 8B, the through-hole 113 is formed on the projecting portion 112b side of the circular ring-shaped portion 112a. In FIG. 8C, the projecting portion 112b is larger than other projecting portions 112b.

For example, as shown in FIGS. 8D to 8F, the circular ring-shaped portion 112a may have an elliptical shape having a long axis in a direction perpendicular to a direction that connects the circular ring-shaped portion 112a and the projecting portion 112b in plan view. In FIG. 8D, the through-hole 113 is formed substantially at the center of the circular ring-shaped portion 112a. In FIG. 8E, the through-hole 113 is formed on the projecting portion 112b side. In FIG. 8F, the projecting portion 112b is larger than other projecting portions 112b.

For example, as shown in FIGS. 8G to 8I, the circular ring-shaped portion 112a may have an elliptical shape with a long axis in a direction that connects the circular ring-shaped portion 112a and the projecting portion 112b in plan view. In FIG. 8G, the through-hole 113 is formed substantially at the center of the circular ring-shaped portion 112a. In FIG. 8H, the projecting portion 112b is larger than other projecting portions 112b, and the through-hole 113 is formed between the center of the circular ring-shaped portion 112a and the projecting portion 112b. In FIG. 8I, the connection position between the circular ring-shaped portion 112a and the projecting portion 112b forms a corner portion, and the through-hole 113 is formed on the projecting portion 112b side.

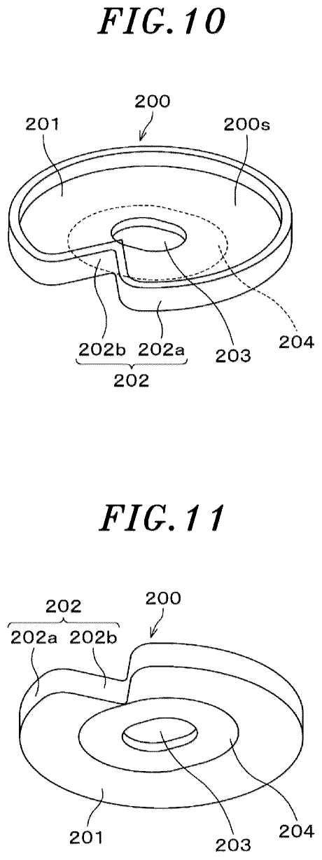

Further, for example, as shown in FIG. 9, the outer base portion 111b may be omitted in the holding pad 110. In this case, the adhesive surface 114b is formed at the tip end of the inner base portion 111a on the projecting portion 112b side.

The above-described effects can also be achieved in the case of using any holding pad 110 shown in FIGS. 8A to 8I and FIG. 9. In other words, the projecting portion 112b, where the stress is concentrated at the time of detaching the wafer W, can function as the detachment starting point, and the rigidity of the projecting portion 112b is increased by the adhesive surface 114b, so that the detachability of the wafer W can be improved. Further, the outer base portion 111b corresponding to the projecting portion 112b is fixed to the pick 100 via the adhesive surfaces 114b and 134b, and has high rigidity. Therefore, stress can be further concentrated on the projecting portion 112b, and the projecting portion 112b can appropriately function as the detachment starting point. Hence, the detachability of the wafer W can be further improved.

In the holding pad 110 described above, the projecting portion 112b projects outward from the circular ring-shaped portion 112a in plan view. However, the projecting portion may project inward from the annular portion.

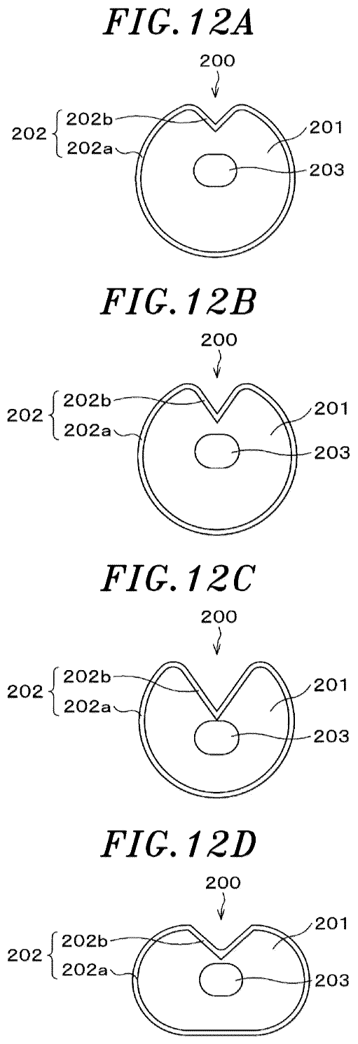

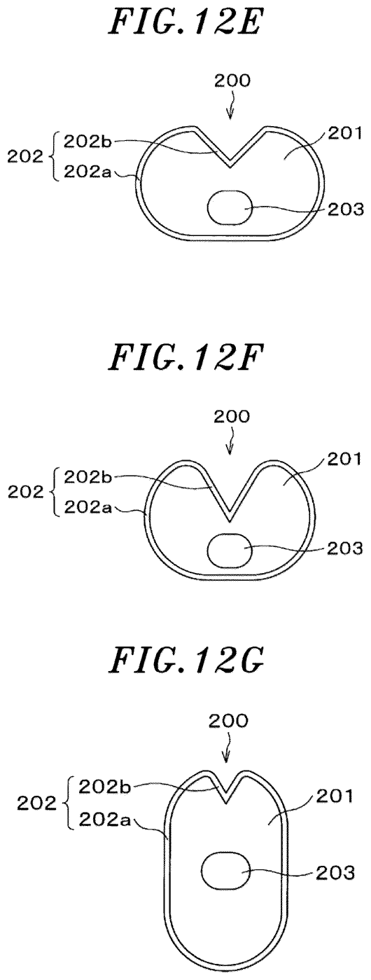

As shown in FIGS. 10 and 11, a holding pad 200 has a base part 201 disposed on the bottom surface, and an annular part 202 disposed on the surface of the base part 201, similarly to the holding pad 110. The base part 201 and the annular part 202 are integrally molded.

The annular part 202 has an annular portion 202a and a projecting portion 202b. The annular portion 202a and the projecting portion 202b are integrally molded. The annular portion 202a has a perfect circular annular shape in plan view, for example. The projecting portion 202b projects inward from the annular portion 202a in a direction intersecting the annular direction of the annular portion 202a in plan view, for example. The vertex of the projecting portion 202b is bent at an acute angle.

A through-hole 203 for vacuum suction is formed in the base part 201. The through-hole 203 is connected to an air supply part 131 for supplying a gas into the holding pad 200, and a suction part 132 for vacuum suctioning of a gas from the holding pad 200.

The holding pad 200 is fixed to the pick 100 via an adhesive.

The back surface of the base portion 201 constitutes an adhesive surface 204 corresponding to the adhesive surface of the pick 100 around the through-hole 203. The adhesive surface 204 is adhesively fixed to the adhesive surface of the pick 100 without a gap. By fixing the periphery of the through-hole 203 and the periphery of the gas channel 130 with the adhesive surface 204, gas leakage can be suppressed. Further, the adhesive surface 204 is formed at a position corresponding to the projecting portion 202b. Therefore, the rigidity of the projecting portion 202b can be increased.

The projecting portion 202b has the same effect as that of the projecting portion 112b described above. In other words, in the case of holding the wafer W using the holding pad 200, a suction space 200s formed between the backside of the wafer W and the inner side of the holding pad 200 is vacuum suctioned by the suction part 132 in a state where the annular part 202 is in contact with the backside of the wafer W.

On the other hand, in the case of detaching the wafer W from the holding pad 200, the vacuum suction of the suction space 200s is stopped, and a gas is supplied from the air supply part 131 to the suction space 200s. Next, when the wafer W is lifted (moved) to be delivered, stress is concentrated on the projecting portion 202b, and the projecting portion 202b becomes the detachment starting point. Then, the wafer W is sequentially detached from the projecting portion 202b toward the annular portion 202a. Therefore, in accordance with the holding pad 200 of the present embodiment, the detachability of the wafer W can be improved. Further, the base part 201 corresponding to the projecting portion 202b is fixed to the pick 100 via the adhesive surface 204 and has high rigidity, the projecting portion 202b can appropriately function as the detachment starting point. Hence, the detachability of the wafer W can be further improved.

Further, the orientation of the three holding pads 200 on the transfer arm 41, that is, the orientation of the projecting portion 202b with respect to the annular portion 202a, is arbitrary. For example, each of the three holding pads 200 may be disposed such that the projecting portion 202b is oriented radially outward from the center of the pick 100 with respect to the annular portion 202a.

Further, in the holding pad 200, the planar shape of the annular portion 202a, the planar shape of the projecting portion 202b, and the arrangement of the through-hole 203 are arbitrary.

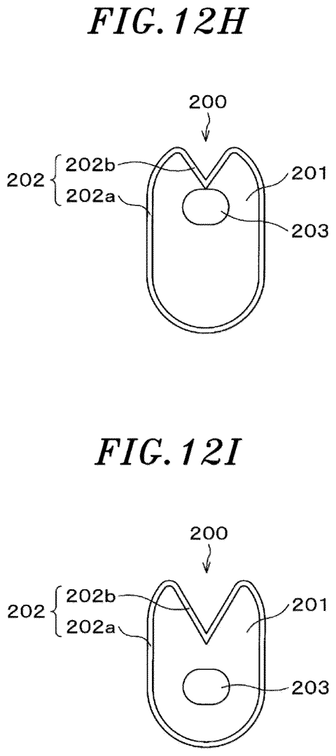

For example, as shown in FIGS. 12A to 12C, the annular portion 202a may have a perfect circular shape in plan view. In FIG. 12A, the through-hole 203 is formed substantially at the center of the annular portion 202a. In FIG. 12B, the projecting portion 202b is larger than other projecting portions 202b of FIG. 12A. In FIG. 12C, the projecting portion 202b is even larger than other projecting portions 202b of FIG. 12B.

For example, as shown in FIGS. 12D to 12F, the annular portion 202a may have an elliptical shape with a long axis in a direction perpendicular to the direction that connects the annular portion 202a and the projecting portion 202b in plan view. In FIG. 12D, the through-hole 203 is formed substantially at the center of the annular portion 202a. In FIG. 12E, the projecting portion 202b is larger than other projecting portions 202b of FIG. 12D, and the through-hole 203 is formed on the opposite side of the projecting portion 202b. In FIG. 12F, the projecting portion 202b is larger than other projecting portions 202b of FIG. 12E, and the through-hole 203 is formed on the opposite side of the projecting portion 202b.

For example, as shown in FIGS. 12G to 12I, the annular portion 202a may have an elliptical shape with a long axis in a direction that connects the annular portion 202a and the projecting portion 202b in plan view. In FIG. 12G, the through-hole 203 is formed substantially at the center of the annular portion 202a. In FIG. 12H, the projecting portion 202b is larger than other projecting portions 202b in FIG. 12G, and the through-hole 203 is formed on the projecting portion 202b side. In FIG. 12I, the projecting portion 202b is larger than other projecting portions 202b of FIG. 12H, and the through-hole 203 is formed on the opposite side of the projecting portion 202b.

In the holding pads 110 and 200 of the above embodiments, the shapes of the annular portions 112a and 202a of the annular portions 112 and 202 are not limited to a perfect circular shape or an elliptical shape. For example, the annular portions 112a and 202a may have an elliptical shape, an egg shape, or the like.

Further, in the holding pads 110 and 200 of the above embodiments, the annular parts 112 and 202 have the annular parts 112a and 202a, respectively, but the overall shape of the annular parts 112 and 202 is not limited to an annular shape. For example, the annular parts 112 and 202 may have a polygonal shape such as a quadrilateral shape or a pentagonal shape. In this case, the annular parts 112 and 202 have polygonal portions (not shown) and the projecting portions 112b and 202b. The above-described effects can also be obtained by the projecting portions 112b and 202b different from the vertex of the polygonal portion. In other words, the detachability of the wafer W can be improved.

Further, the material of the holding pads 110 and 200 of the above embodiments is not particularly limited. For example, polyimide (PI) resin, polyetheretherketone (PEEK) resin, or polyphenylene sulfide (PPS) resin may be used. However, the present inventors have found, as a result of intensive study, that it is preferable to use PI resin after comprehensive examination of the detachability of the wafer W and the adsorption property (leakage property) of the wafer W.

Further, in the annular parts 112 and 202 of the holding pads 110 and 200, the material of the projecting portions 112b and 202b may be different from that of the annular portions 112a and 202a. For example, the projecting portions 112b and 202b may be made of a material having high rigidity, or may be made of a material having high detachability.

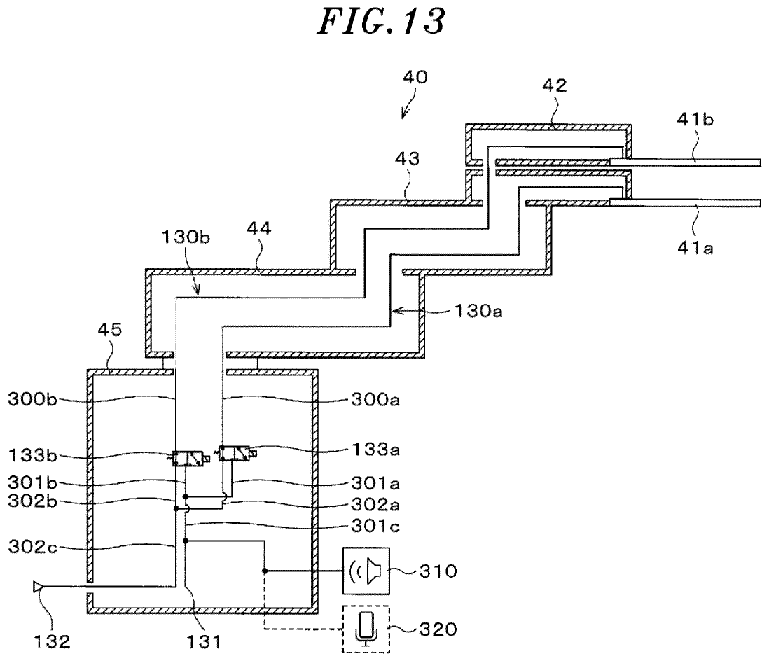

Next, the configuration of the wafer transfer device 40 according to another embodiment will be described. FIG. 13 is an explanatory diagram showing the internal configuration of the wafer transfer device 40. In the following description, the transfer arm 41a of the wafer transfer device 40 may be referred to as “lower transfer arm 41a,” and the transfer arm 41b may be referred to as “upper transfer arm 41b.”

The gas channel 130 described above includes a lower gas channel 130a connected to the lower transfer arm 41a, and an upper gas channel 130b connected to the upper transfer arm 41b. Further, the valve 133 described above includes a lower valve 133a disposed in the lower gas channel 130a, and an upper valve 133b disposed in the upper gas channel 130b. For example, a solenoid valve is used for the valves 133a and 133b. However, the valves 133a and 133b are not limited to solenoid valves as long as they can switch gas supply and gas suction as will be described later.

The lower gas channel 130a has a lower gas main channel 300a, a lower gas supply line 301a, and a lower gas suction passage 302a. The lower gas main channel 300a connects the holding pad 110 and the lower valve 133a. The lower gas supply line 301a is connected to the lower valve 133a, and supplies a gas to the lower main gas channel 300a. The lower gas suction passage 302a is connected to the lower valve 133a, and conducts suction of a gas from the lower gas main channel 300a.

The upper gas channel 130b has the same configuration as that of the lower gas channel 130a, and has an upper gas main channel 300b, an upper gas supply line 301b, and an upper gas suction passage 302b. The upper gas main channel 300b connects the holding pad 110 and the upper valve 133b. The upper gas supply line 301b is connected to the upper valve 133b, and supplies a gas to the upper gas main channel 300b. The upper gas suction passage 302b is connected to the upper valve 133b, and conducts suction of a gas from the upper gas main channel 300b.

The lower gas supply line 301a and the upper gas supply line 301b join on the opposite side of the valves 133a and 133b, thereby forming a gas supply line 301c. The gas supply line 301c is opened to the atmospheric atmosphere in the rotatable table 45. In other words, the gas supply lines 301a to 301c are maintained at the atmospheric atmosphere. Further, the air supply part 131 described above corresponds to the inside (atmospheric atmosphere) of the rotatable table 45.

The lower gas suction passage 302a and the upper gas suction passage 302b join on the opposite side of the valves 133a and 133b, thereby forming a gas suction passage 302c. The gas suction passage 302c is connected to the suction part 132 described above.

In the case of holding the wafer W using the holding pad 110 in the lower transfer arm 41a, the lower gas main channel 300a and the lower gas suction passage 302a are connected by the lower valve 133a. The suction part 132 operates constantly, and the gas suction passage 302c and the lower gas suction passage 302a are constantly vacuum suctioned. Then, when the annular part 112 of the holding pad 110 is brought into contact with the backside of the wafer W, the gas in the suction space 110s of the holding pad 110 flows through the gas suction passage 302c, the lower gas suction passage 302a, and the lower gas main channel 300a, and the suction space 110s is evacuated. In this manner, the wafer W is held by the holding pad 110.

On the other hand, in the case of detaching the wafer W from the holding pad 110, the lower gas main channel 300a and the lower gas supply line 301a are connected by the lower valve 133a. The lower gas supply line 301a and the gas supply line 301c are maintained in an atmospheric atmosphere, and the gas in the lower gas supply line 301a is supplied to the suction space 110s via the lower gas main channel 300a. Then, the lower gas main channel 300a and the suction space 110s are maintained at atmospheric pressure. In this manner, the wafer W is detached from the holding pad 110.

A speaker 310 as a vibration imparting part is disposed in the gas supply line 301c. The speaker 310 generates sound waves. As described above, in the case of detaching the wafer W from the holding pad 110, a gas is supplied to the suction space 110s through the gas supply line 301c, the lower gas supply line 301a, and the lower gas main channel 300a, and the insides thereof are filled with a gas of an atmospheric pressure. If sound waves are generated from the speaker 310 at this time, the sound waves are transmitted to the holding pad 110 via the gas. Then, the holding pad 110 vibrates due to the sound waves, and the vibration causes detachment, which makes it possible to further improve the detachability.

Further, by optimizing the frequency or the output of the sound waves generated from the speaker 310, the holding pad 110 can be appropriately vibrated. For example, the frequency of the sound waves preferably coincides with the natural frequency of the holding pad 110.

Here, in order to improve the detachability of the wafer W, it is considered to pressurize the gas channel 130 (the lower gas channel 130a and the upper gas channel 130b) connected to the holding pad 110. However, in this case, a gas flows out from the holding pad 110 immediately after the wafer W is detached, which may cause scattering of particles in the gas channel 130. Therefore, in view of suppressing scattering of particles, it is effective to vibrate the holding pad 110 using sound waves as in the present embodiment.

Further, the timing at which the speaker 310 generates sound waves is not particularly limited. For example, the sound waves may be constantly generated from the speaker 310. In that case, in the case of holding the wafer W using the holding pad 110, the suction space 110s is vacuum suctioned via the lower gas main channel 300a, so that the sound waves from the speaker 310 do not transmit the vacuum atmosphere, and are not transmitted to the holding pad 110. Therefore, the holding pad 110 can be vibrated by the sound waves only when it is required to detach the wafer W from the holding pad 110. In other words, the sound waves can be appropriately transmitted to the holding pad 110 simply by switching the lower valve 133a. Alternatively, in view of energy saving, the speaker 310 may generate sound waves only when it is required to detach the wafer W from the holding pad 110.

In the present embodiment, in the case of detaching the wafer W, the holding pad 110 is vibrated. However, the wafer W held by the holding pad 110 may be vibrated. In that case, the frequency of the sound waves preferably coincides with the natural frequency of the wafer W, for example. Alternatively, both the holding pad 110 and the wafer W may be vibrated by adjusting the frequency or the output of the sound waves.

Further, although the case where the wafer W is held by the holding pad 110 and detached from the holding pad 110 in the lower transfer arm 41a have been described in the present embodiment, the present disclosure is also applied to the case where the wafer W is held on or detached from the upper transfer arm 41b. In the present embodiment, the speaker 310 is disposed in the gas supply line 301c shared by the lower transfer arm 41a and the upper transfer arm 41b, so that the holding pads 110 (or the wafers W) of both transfer arms 41a and 41b can be vibrated.

Although it is preferable that the speaker 310 is provided commonly for the transfer arms 41a and 41b in view of device simplification, the arrangement of the speaker 310 is not limited thereto. For example, the speaker 310 may be individually provided for each of the lower transfer arm 41a and the upper transfer arm 41b. In that case, two speakers 310 are provided in the lower gas supply line 301a and the upper gas supply line 301b, respectively.

Further, although the speaker 310 is used as the vibration imparting part in the present embodiment, the present disclosure is not limited thereto as long as the holding pad 110 (or the wafer W) can be vibrated. For example, sound waves may be generated using an audio device other than the speaker 310 as the vibration imparting part. Alternatively, an ultrasonic generator for generating ultrasonic waves may be used as the vibration imparting part.

In addition to the speaker 310, a microphone 320 as a vibration detection part may be disposed in the gas supply line 301c of the above embodiment. The microphone 320 detects echo returning from the wafer W when the sound waves generated from the speaker 310 are reflected by the wafer W held by the holding pad 110.

As described above, in the case of detaching the wafer W from the holding pad 110 in the lower transfer arm 41a, for example, the inside of the lower gas channel 130a and the suction space 110s are filled with a gas of an atmospheric pressure, and the speaker 310 generates sound waves to vibrate the holding pad 110. In this case, if the microphone 320 detects echo from the wafer W, it is determined that the wafer W exists on the holding pad 110, which can confirm that the wafer W has not been detached. On the other hand, if the microphone 320 does not detect echo, it is determined that no wafer exists on the holding pad 110, which can confirm that the wafer W has been properly detached. In this manner, the presence of absence of the wafer W can be checked by the presence or absence of echo detected by the microphone 320.

Here, in order to check the presence or absence of the wafer W on the holding pad 110, it is considered to use an internal pressure of the lower gas channel 130a (in particular, an internal pressure of the lower gas main channel 300a). For example, when the internal pressure is high, it is determined that the wafer W exists on the holding pad 110. On the other hand, when the internal pressure is low, it is determined that the wafer W does not exist on the holding pad 110. However, in order to confirm that there is no wafer W in the case of detaching the wafer W from the holding pad 110, it is necessary to lower the pressure in the lower gas channel 130a to a predetermined threshold value, which takes time. In this regard, in accordance with the present embodiment, the presence or absence of the wafer W is confirmed by detecting the presence or absence of echo, the time required for confirmation can be shortened.

Further, although the case where the wafer W is held by the holding pad 110 and detached from the holding pad 110 in the lower transfer arm 41a has been described, the present disclosure can also be applied to the case where the wafer W is held or detached in the upper transfer arm 41b.

Further, it is also possible to simultaneously check the presence or absence of the wafer W on the lower transfer arm 41a and the presence or absence of the wafer W on the upper transfer arm 41b. For example, when the microphone 320 detects echo from two wafers W, the intensity of echo increases. Therefore, whether there are two wafers W, one wafer W, or no wafer W can be checked depending on the intensity of echo. Further, the length of the lower gas channel 130a and the length of the upper gas channel 130b are different. Therefore, when there is one wafer W, echo from the wafer W on the lower transfer arm 41a and echo from the wafer W on the upper transfer arm 41b are detected at different timings. In other words, the microphone 320 quickly detects echo from the wafer W on the lower transfer arm 41a. Therefore, when there is one wafer W, whether the wafer W is located on the lower transfer arm 41a or the upper transfer arm 41b can be checked by the detection timing of echo. Further, in the present embodiment, the microphone 320 is provided in the gas supply line 301c shared by the lower transfer arm 41a and the upper transfer arm 41b, so that the presence or absence of the wafer W in the lower transfer arm 41a and the presence or absence of the wafer W in the upper transfer arm 41b can be checked simultaneously.

Although it is preferable to provide the microphone 320 commonly for the transfer arms 41a and 41b in view of device simplification, the arrangement of the microphone 320 is not limited thereto. For example, the microphone 320 may be individually provided for each of the lower transfer arm 41a and the upper transfer arm 41b. In this case, two microphones 320 are provided in the lower gas supply line 301a and the upper gas supply line 301b, respectively.

Further, the combined arrangement of the speaker 310 and the microphone 320 is not limited to the present embodiment. Various combinations, such as combination of one speaker 310 and two microphones, combination of two speakers 310 and one microphone, and combination of two speakers 310 and two microphones, are considered.

Further, although the microphone 320 is used as the vibration imparting part in the present embodiment, the vibration imparting part is not limited to the microphone as long as echo can be detected.

Further, the microphone 320 as the vibration detection part of the present embodiment can also be used for purposes other than the detection of the presence or absence of the wafer W. For example, Japanese Patent No. 6114060 discloses that when a wafer is received by a transfer arm, the wafer delivery position is confirmed based on the ascending amount of the transfer arm and the contact sound between the transfer arm and the wafer. For example, the microphone 320 of the present embodiment may be used for detecting the contact sound between the transfer arm 41 and the wafer W.

It should be noted that the embodiments of the present disclosure are illustrative in all respects and are not restrictive. The above-described embodiments may be omitted, replaced, or changed in various forms without departing from the scope of the appended claims and the gist thereof.

Further, the following configuration examples are also included in the technical scope of the present disclosure.

(1) A transfer arm for vacuum suctioning and transferring a substrate under an atmospheric atmosphere, comprising:
a pick configured to hold a substrate; and
a plurality of holding pads disposed on a surface of the pick,
wherein each of the holding pads includes:
   a base part disposed on a surface of the pick and having a through-hole for vacuum suction; and
   an annular part disposed in an annular shape on the surface of the base part and configured to be in contact with a backside of the substrate,
wherein a part of the annular part has a projecting portion formed in a direction intersecting with an annular direction of the annular part.

(2) The transfer arm of (1), wherein the annular part has a circular ring shape.

(3) The transfer arm of (1) or (2), wherein the projecting portion is formed on either an outer side or an inner side of the annular part.

(4) The transfer arm of (3), wherein the projecting portion is formed on the outer side of the annular part.

(5) The transfer arm of any one of (1) to (4), wherein a vertex of the projecting portion is bent at an acute angle.

(6) The transfer arm of any one of (1) to (5), wherein the base part is fixed to the surface of the pick via an adhesive, and
an adhesive surface to be adhered to the surface of the pick is formed on a back surface of the base part at a location corresponding to the projecting portion.

(7) The transfer arm of (6), wherein an adhesive surface with the surface of the pick is formed around the through-hole on the back surface of the base part.

(8) A substrate transfer device for transferring a substrate under an atmospheric atmosphere, comprising:
a transfer arm configured to vacuum suction and transfer a substrate,
wherein the transfer arm includes:
   a pick configured to hold a substrate; and
   a plurality of holding pads disposed on a surface of the pick,
wherein each of the holding pads includes:
   a base part disposed on the surface of the pick and having a through-hole for vacuum suction; and
   an annular part disposed in an annular shape on a surface of the base part and configured to be in contact with a backside of the substrate,
wherein a part of the annular part has a projecting portion formed in a direction intersecting with an annular direction of the annular part.

(9) The substrate transfer device of (8), further comprising:
a gas channel that is connected to the holding pad and supplies a gas to the holding pad or conducts suction of a gas; and
a vibration imparting part disposed in the gas channel and configured to impart vibration to at least one of the holding pad or the substrate held by the holding pad.

(10) The substrate transfer device of (9), wherein the gas channel is provided with a valve that switches supply of the gas and suction of the gas,
the gas channel includes a main gas channel that connects the holding pad and the valve, a gas supply line that is connected to the valve and supplies a gas to the main gas channel, and a gas suction line that is connected to the valve and conducts suction of a gas from the main gas channel, and
the vibration imparting part is disposed in the gas supply line.

(11) The substrate transfer device of (9) or (10), further comprising:
a vibration detection part disposed in the gas channel and configured to detect vibration applied by the vibration imparting part.

(12) The substrate transfer device of (11), wherein the gas channel is provided with a valve that switches supply of the gas and suction of the gas,
the gas channel includes a main gas channel that connects the holding pad and the valve, a gas supply line that is connected to the valve and supplies a gas to the main gas channel, and a gas suction line that is connected to the valve and conducts suction of a gas from the main gas channel, and
the vibration detection part is disposed in the gas supply line.

### DESCRIPTION OF REFERENCE NUMERALS

40: wafer transfer device
41 (41a, 41b): transfer arm
100: picks
110: holding pad
111: base part
112: annular part
113: through-hole
112b: projecting portion
W: wafer

1. transfer arm for vacuum suctioning and transferring a substrate under an atmospheric atmosphere, comprising:
a pick configured to hold a substrate; and
a plurality of holding pads disposed on a surface of the pick,
wherein each of the plurality of holding pads includes:
a base part disposed on a surface of the pick and having a through-hole for vacuum suction; and
an annular part disposed in an annular shape on the surface of the base part and configured to be in contact with a backside of the substrate,
wherein a part of the annular part has a projecting portion in a direction intersecting with an annular direction of the annular part, and
the annular part has a circular ring shape.

2. (canceled)

3. The transfer arm of claim 1, wherein the projecting portion is on either an outer side or an inner side of the annular part.

4. The transfer arm of claim 3, wherein the projecting portion is on the outer side of the annular part.

5. The transfer arm of claim 1, wherein a vertex of the projecting portion is bent at an acute angle.

6. The transfer arm of claim 1, wherein the base part is fixed to the surface of the pick via an adhesive, and
an adhesive surface to be adhered to the surface of the pick is on a back surface of the base part at a location corresponding to the projecting portion.

7. The transfer arm of claim 6, wherein an adhesive surface with the surface of the pick is around the through-hole on the back surface of the base part.

8. A substrate transfer device for transferring a substrate under an atmospheric atmosphere, comprising:
a transfer arm configured to vacuum suction and transfer a substrate,
wherein the transfer arm includes:
a pick configured to hold a substrate; and
a plurality of holding pads disposed on a surface of the pick,
wherein each of the plurality of holding pads includes:
a base part disposed on the surface of the pick and having a through-hole for vacuum suction; and
an annular part disposed in an annular shape on a surface of the base part and configured to be in contact with a backside of the substrate,
wherein a part of the annular part has a projecting portion in a direction intersecting with an annular direction of the annular part, and
the annular part has a circular ring shape.

9. The substrate transfer device of claim 8, further comprising:
a gas channel that is connected to a holding pad from the plurality of holding pads and supplies a gas to the holding pad or conducts suction of a gas; and
a vibration imparting part disposed in the gas channel and configured to impart vibration to at least one of the holding pad or the substrate held by the holding pad.

10. The substrate transfer device of claim 9, wherein the gas channel is provided with a valve that switches supply of the gas and suction of the gas,
the gas channel includes a main gas channel that connects the holding pad and the valve, a gas supply line that is connected to the valve and supplies a gas to the main gas channel, and a gas suction line that is connected to the valve and conducts suction of a gas from the main gas channel, and
the vibration imparting part is disposed in the gas supply line.

11. The substrate transfer device of claim 9, further comprising:
a vibration detection part disposed in the gas channel and configured to detect vibration applied by the vibration imparting part.

12. The substrate transfer device of claim 11, wherein the gas channel is provided with a valve that switches supply of the gas and suction of the gas,
the gas channel includes a main gas channel that connects the holding pad and the valve, a gas supply line that is connected to the valve and supplies a gas to the main gas channel, and a gas suction line that is connected to the valve and conducts suction of a gas from the main gas channel, and
the vibration detection part is disposed in the gas supply line.

13. The substrate transfer device of claim 10, further comprising:
a vibration detection part disposed in the gas channel and configured to detect vibration applied by the vibration imparting part.

14. The substrate transfer device of claim 13, wherein the gas channel is provided with a valve that switches supply of the gas and suction of the gas,
the gas channel includes a main gas channel that connects the holding pad and the valve, a gas supply line that is connected to the valve and supplies a gas to the main gas channel, and a gas suction line that is connected to the valve and conducts suction of a gas from the main gas channel, and
the vibration detection part is disposed in the gas supply line.
